(19) United States
(12) Patent Application Publication
(10) Pub. No.: US 2008/0090312 A1
(43) Pub. Date: Apr. 17, 2008

(54) LITHOGRAPHY ALIGNMENT SYSTEM AND METHOD USING nDSE-BASED FEEDBACK CONTROL

(76) Inventors: Inkyu Park, Albany, CA (US); Wei Wu, Mountain View, CA (US); Jun Gao, Saratoga, CA (US); Carl E. Picciotto, Menlo Park, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/550,372

(22) Filed: Oct. 17, 2006

(51) Int. Cl. H01L 21/66

(52) U.S. Cl. 438/14

(57) ABSTRACT

A contact lithography alignment system and method use nanoscale displacement sensing and estimation (nDSE) to maintain an alignment and compensate for a disturbance of one or more objects during contact lithography. A method of maintaining an alignment includes establishing an initial alignment of one or more objects and employing nDSE-based feedback control of relative positions of more or more of the objects to maintain the alignment during contact lithography. A method of disturbance compensation includes acquiring a first image, acquiring a second image, estimating an alignment error using nDSE applied to the first and second image, and adjusting a relative position to reduce the alignment error. A contact lithography system includes an optical sensor, a feedback processor providing nDSE and a position controller that adjusts relative positions of one or more objects to reduce an alignment error determined using the nDSE.

### CROSS-REFERENCE TO RELATED APPLICATIONS

N/A

### STATEMENT REGARDING FEDERALLY SPONSORED RESEARCH OR DEVELOPMENT

N/A

### BACKGROUND

1. Technical Field

The invention relates to semiconductors and the fabrication thereof. In particular, the invention relates to contact and/or imprint lithography used to define one or both of microscale and nanoscale structures during semiconductor fabrication.

2. Description of Related Art

Photographic contact lithography and imprint lithography are examples of two lithography methodologies for defining microscale and nanoscale structures that generally involve direct contact between a patterning tool (e.g., mask, mold, template, etc.) and a substrate on which the structures are to be fabricated. In particular, during contact lithography, the patterning tool (i.e., mask) is aligned with and then brought in contact with the substrate or a pattern receiving layer of the substrate. Similarly, in imprint lithography, the patterning tool (i.e., mold) is aligned with the substrate after which the pattern is printed on or impressed into a receiving surface of the substrate. With either method, alignment between the patterning tool and the substrate generally involves holding the patterning tool a small distance above the substrate while lateral and rotational adjustments (e.g., x-y translation and/or angular rotation) are made to a relative position of one or both of the tool and the substrate. The patterning tool is then brought in contact with the substrate to perform the lithographic patterning.

In both of contact lithography and imprint lithography, an ultimate alignment accuracy as well as an achievable patterning resolution may be adversely affected by disturbances of an initial alignment or a desired alignment during lithography. The disturbances may be due to influences external to the lithography system. In addition, drift or slip in the relative positioning of the aligned patterning tool and substrate within the lithography system may disturb the alignment.

### BRIEF SUMMARY

In some embodiments of the present invention, a method of maintaining an alignment during lithography is provided. The method of maintaining an alignment comprises establishing an initial alignment of one or more objects. The method of maintaining an alignment further comprises employing feedback control of relative positions of one or more of the objects to maintain the alignment during contact lithography. The feedback control comprises using nanoscale displacement sensing and estimation (nDSE).

In other embodiments of the present invention, a method of disturbance compensation during contact lithography is provided. The method of disturbance compensation comprises acquiring a first image of a patterning tool and a substrate being patterned by the contact lithography. The first image is acquired after establishing an alignment between the patterning tool and the substrate. The method of disturbance compensation further comprises acquiring a second image of the patterning tool and the substrate after a disturbance of the alignment, the disturbance degrading the alignment. The method of disturbance compensation further comprises estimating an alignment error induced by the disturbance using nanoscale displacement sensing and estimation (nDSE) applied to the first image and the second image. The method of disturbance compensation further comprises adjusting a relative position of the patterning tool and the substrate to reduce the alignment error.

In other embodiments of the present invention, a contact lithography alignment system is provided. The contact lithography alignment system comprises an optical sensor that produces an image of one or more objects being aligned. The contact lithography alignment system further comprises a feedback processor providing nanoscale displacement sensing and estimation (nDSE). The feedback processor receives the image from the optical sensor and determines an alignment error from the image using the nDSE. The alignment error is relative to an initial alignment of the objects. The contact lithography alignment system further comprises a position controller that adjusts relative positions of one or more of the objects to reduce the alignment error determined by the feedback processor.

Certain embodiments of the present invention have other features that are one or both of in addition to and in lieu of the features described hereinabove. These and other features of the invention are detailed below with reference to the following drawings.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1 illustrates a flow chart of a method of maintaining an alignment during lithography according to an embodiment of the present invention.

FIG. 2 illustrates a flow chart of employing feedback control according to an embodiment of the present invention.

FIG. 3A illustrates a flow chart of an embodiment of using nanoscale displacement sensing and estimation (nDSE) according to the present invention.

FIG. 3B illustrates a flow chart of another embodiment of using nanoscale displacement sensing and estimation (nDSE) according to the present invention.

FIG. 4 illustrates a flow chart of a method of disturbance compensation during contact lithography according to an embodiment of the present invention.

FIG. 5 illustrates a block diagram of a contact lithography alignment system according to an embodiment of the present invention.

FIG. 6 illustrates a block diagram of a feedback processor providing nanoscale displacement sensing and estimation (nDSE) according to an embodiment of the present invention.

### DETAILED DESCRIPTION

The embodiments of the present invention facilitate employing lithography to apply a pattern to a substrate (i.e., “patterning a substrate”). In some embodiments, the lithography comprises contact lithography involving a contact between a patterning tool and a substrate. In various embodiments, the present invention employs nanoscale displacement sensing and estimation (nDSE) to estimate and reduce and effect of a disturbance on an alignment associated with the lithography. The nDSE is image-based according to the present invention. In particular, the present invention employs images of aligned objects acquired before and after the disturbance. In some embodiments, the images are optical images. The disturbance is one or more of induced by a contact between the aligned objects, associated with differential vibration of aligned objects, produced by a temperature differential between and across aligned objects, and generated by a mechanical drift or slippage of a lithography system operating on the objects, according to various embodiments of the present invention.

As used herein, nanoscale displacement sensing and estimation (nDSE) is an image-based methodology for detecting and quantifying a relative displacement of or between one or more objects using a pair of images of the objects. In particular, as defined herein nDSE is essentially any methodology that employs a comparison of pixel-level data contained in the pair of images to estimate one or both of a magnitude and a direction of the relative displacement (i.e., a vector displacement). In some embodiments, nDSE comprises one or more of phase delay detection-based (PDD-based) nDSE, statistical image correlation-based nDSE, and feature extraction-based nDSE applied to the images. Using nDSE, sub-pixel resolution of an estimated relative displacement often can be achieved. For example, a statistical image correlation using nearest neighbor (N-cubed) algorithms can provide a displacement estimate resolution of less than or equal to about 1/100^{th} of a pixel.

PDD-based nDSE models a relative displacement of objects in terms of a constant phase delay across frequencies present within a frequency-domain transformation of the pixel-level data of images of the object. As an algorithm, phase delay detection (PDD) is based on a shift property of frequency-domain transformations, such as the Fourier transform. To estimate displacement, PDD extracts the phase delay from a pair of transformed images by observing phases of the frequencies before and after a displacement of the objects as recorded by the images. A slope of the extracted phase delay provides the estimated displacement of the objects. PDD is generally considered to be a global method with a capacity to handle relatively large relative displacements with reasonable computational complexity. PDD also provides for an ability to compensate for colored noise sources that may be present in the images. PDD-based nDSE is described further by Gao et al., in U.S. Patent Application Publication, US 2006-0045314 A1, incorporated herein by reference.

Statistical image correlation-based nDSE employs variations of a nearest neighbor navigation (N-cubed) algorithm. The statistical image correlation-based nDSE statistically extracts a relative displacement of the objects represented in a pair of images (i.e., an image before and an image after displacement) by correlating one or both of features and patterns within the image. In particular, values of neighboring pixels in the images are correlated and a result is fit to a function. An extremum (i.e., a minimum or a maximum) of the fitted function then provides the relative displacement estimate. Statistical image correlation-based nDSE is generally considered to be a local method with an ability to handle relatively small displacements and often to provide much higher resolution than the PDD-based nDSE. While somewhat less able to deal with colored noise sources than PDD-based nDSE, statistical image correlation-based nDSE is generally more efficient to implement and maintain. In addition, statistical image correlation-based nDSE may be more robust when presented with white noise than the PDD-based nDSE. Statistical image correlation-based nDSE is described further by Gao et al., U.S. Patent Application Publication, US 2006-0045313 A1, incorporated herein by reference.

Feature extraction-based nDSE estimates a relative displacement using image features or patterns extracted from the pair of images. In particular, one or more image features are identified in a first image of the pair. A corresponding one or more image features is identified in a second image of the pair. For example, edge detection may be employed to identify the one or more features (e.g., edges of or within the objects). In other examples, any one of various object identification techniques is used to identify the features (e.g., specific elements of the objects). Locations of the identified features are then compared between the two images to estimate the relative displacement. For example, a middle or centroid of an identified object in the first and second images may be determined. A difference in a location of the respective determined middles is the measured. The measured difference provides an estimate of the relative displacement of the objects.

Estimates of a relative displacement are provided by nDSE, according to the present invention. As used herein, nDSE generally does not track an actual position of the object or objects. The relative displacement (i.e., offset) may comprise a displacement of an object(s) relative to a reference frame, in some embodiments. For example the relative displacement may be a displacement of the object relative to a camera producing the images. In other embodiments the relative displacement estimate represents relative displacement of an object with respect to another object or objects being imaged. For example, the relative displacement may be between a patterning tool (e.g., mask, mold, etc.) and a substrate using features visible separately on each of the patterning tool and the substrate. Such relative displacement estimates are readily produced by nDSE. Moreover, once aligned, nDSE can detect and quantify a change in an alignment between objects (e.g., the patterning tool and the substrate). Estimating relative displacements using nDSE is further described by Picciotto et al., U.S. Pat. No. 7,085,673, as well as by Picciotto et al., U.S. Patent Application Publication, US 2006-0047462 A1, both of which are incorporated herein by reference, in their entireties.

The displacement estimate produced by nDSE does not employ specific image information (e.g., an alignment mark or pattern) but instead employs arbitrary image features and patterns encoded in the pixel-level data. The use of arbitrary image features and patterns in the objects distinguishes nDSE used for object alignment from conventional alignment approaches that require a high-precision alignment mark to detect and quantify misalignments and displacements. Furthermore, the image features and patterns employed by nDSE are generally not optically colocated (i.e., not visually aligned on top of one another) as required for alignment marks employed in conventional alignment. Instead, nDSE employs image features and patterns that are optically nearby but not visually occluding one another. For example, an arbitrary image feature on a patterning tool employed by nDSE may be visually adjacent to another arbitrary image feature on the substrate when viewed from a perspective of an optical sensor (e.g., camera). However, while generally not employing image features and patterns that are optically colocated, nDSE is capable of employing optically colocated image features and patterns instead of or in addition to those that are not optically colocated.

Further herein, the term ‘contact lithography’ generally refers to essentially any lithographic methodology that employs a direct or physical contact between means for providing a pattern or the patterning tool and means for receiving the pattern or the substrate, including a substrate having a pattern receiving layer, without limitation. Specifically, ‘contact lithography’ as used herein includes, but is not limited to, various forms of photographic contact lithography, X-ray contact lithography, and imprint lithography. Imprint lithography includes, but is not limited to, micro-imprint lithography and nano-imprint or nanoscale imprint lithography (NIL).

For example, in photographic contact lithography, a physical contact is established between a photomask (i.e., the patterning tool) and a photosensitive resist layer on the substrate (i.e., the pattern receiving means). During the physical contact, visible light, ultraviolet (UV) light, or another form of radiation passing through the photomask exposes the photoresist. As a result, a pattern of the photomask is transferred to the substrate. In imprint lithography, a mold (i.e., the patterning tool) transfers a pattern to the substrate through an imprinting process, for example. In some embodiments, a physical contact between the mold and a layer of formable or imprintable material on the substrate (i.e., the pattern receiving means), transfers the pattern to the substrate.

For simplicity herein, no distinction is made between the substrate and any layer or structure on the substrate (e.g., photoresist layer or imprintable material layer) unless such a distinction is necessary for proper understanding. As such, the pattern receiving means is generally referred to herein as a ‘substrate’ irrespective of whether a resist layer or a formable layer may be employed on the substrate to receive the pattern. Moreover, the patterning tool (e.g., photomask, X-ray mask, imprint mold, template, etc.) is also referred to herein as either a ‘mold’ or a ‘mask’ for simplicity of discussion and not by way of limitation. Examples described herein are provided for illustrative purposes only and not by way of limitation.

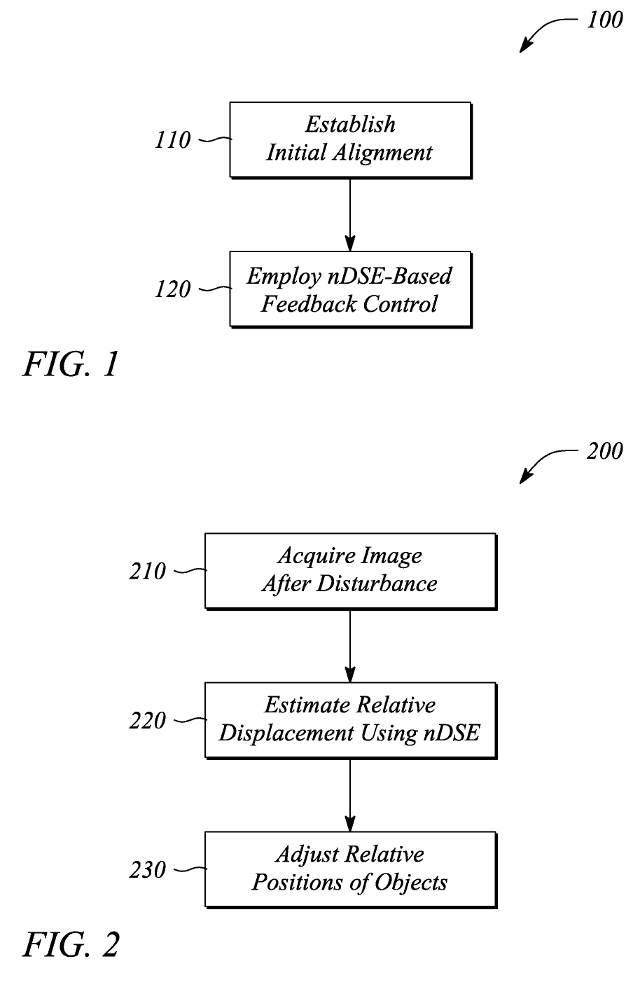

FIG. 1 illustrates a flow chart of a method 100 of maintaining an alignment during lithography according to an embodiment of the present invention. The method 100 of maintaining an alignment comprises establishing 110 an initial alignment of one or more objects. As used herein, “initial alignment” means a desired alignment of the objects before a disturbance. In some embodiments, establishing 110 an initial alignment comprises aligning the objects relative to a reference frame. For example, the objects may be positioned during establishing 110 to be centered in a grid of the reference frame (e.g., a center of the objects may be aligned with an origin of a Cartesian coordinate system). The reference frame may be defined by a location of an optical sensor, for example.

In other embodiments, establishing 110 an initial alignment comprises aligning separate ones of the objects with respect to one another. In particular, establishing 110 an initial alignment establishes a relative orientation of a plurality of objects. For example, establishing 110 an initial alignment may align a patterning tool (or a pattern thereon) with a substrate being patterned, each of the patterning tool and substrate representing an object of the plurality. Establishing 110 establishes a relative positioning of the patterning tool and the substrate, according to the embodiment. In general, the established 110 initial alignment may be one or both of a lateral alignment (e.g., x-y) and an angular alignment (e.g., ω alignment) of the patterning tool relative to the substrate.

In some embodiments, establishing 110 an initial alignment comprises manually adjusting one or both of a position and an orientation of the objects. For example, an operator may observe the objects and manually command a positioning system to move the objects (e.g., one or more of the objects may be moved) until a desired alignment is achieved. An alignment operation of a conventional mask aligner system is an example of establishing 110 an initial alignment of an exemplary patterning tool and substrate.

In other embodiments, establishing 110 an initial alignment comprises automatically aligning the objects (e.g., a relative position of the patterning tool and the substrate). An automated alignment system compares a current position of an object or objects relative to a desired position or positions and provides an input to the positioning system that adjusts positions or relative positions of the objects to correspond to desired positions, for example. In some embodiments of establishing 110 an initial alignment automatically, nDSE is employed to measure a displacement error between the current position and the desired position. Once the displacement error is determined, one or more of the objects are moved by the positioning system to the desired position or positions. Generally, establishing 110 an initial alignment is performed before or at a beginning of the lithography process.

The method 100 of maintaining an alignment further comprises employing 120 nanoscale displacement sensing and estimation (nDSE) based feedback control of relative positions of one or more of the objects. In particular, employing 120 nDSE-based feedback control uses nDSE to quantify a relative displacement of the objects from the established 110 initial position. Employing 120 nDSE-based feedback control maintains the alignment during the lithography process. Specifically, the quantified relative displacement is reduced and, in some embodiments, minimized by nDSE-based feedback control of the position. The nDSE-based feedback control of the position accounts and corrects for disturbances of the object after the initial alignment is established 110.

The disturbance of the objects after initial alignment represents a change in the alignment (i.e., one or both of a location and an orientation) of the objects relative to the initial alignment. The change degrades the alignment. In general, the disturbance may be one or both of a periodic disturbance and an aperiodic disturbance. A periodic disturbance is a change in the alignment of the objects that is repeating and is characterized by a disturbance frequency. A periodic disturbance may have multiple, discrete disturbance frequencies. An aperiodic disturbance is generally non-repeating and may be represented by a continuous range of disturbance frequencies. Whether periodic, aperiodic, or both, the disturbance may be represented by a frequency spectrum. A Nyquist rate or frequency is defined as two (2) times a highest frequency of interest in the frequency spectrum. In some embodiments, a highest frequency of interest is determined by a frequency in the frequency spectrum above which a power of the spectrum is sufficiently small to be ignored. In some embodiments, the highest frequency of interest is a point in the frequency spectrum above which the disturbance essentially does not interfere with an alignment of the objects as defined by a predetermined alignment accuracy.

In some instances, the disturbance may be due to or be a result of a vibration in the environment. Such environmental vibrations may be mechanical vibrations transmitted through a table or bench that supports a lithography system that performs the lithography. Examples of mechanical vibrations include, but are not limited to, people walking in a vicinity of the lithography system or equipment being moved in the vicinity of the lithography system. Such mechanical vibrations are often present even when using one or both of a passive vibration isolation system and an active vibration isolation system, for example. Such mechanical vibrations can be both periodic and aperiodic. Other environmental vibrations may be acoustic vibrations. Acoustic vibrations are often associated with an air ventilation system or other clean room equipment, for example. Acoustic vibrations are generally coupled to the lithography system through the air surrounding the system. Acoustic vibrations of significance are largely periodic.

In some instances, the disturbance may be a result of a temperature difference within or between the objects or within an environment through which the objects are moved. For example, a thermal expansion or contraction that introduces a relative displacement between the patterning tool and the substrate may occur during lithography. Temperature differences are typically aperiodic and characterized by mostly low frequency spectral components.

In other instances, the disturbance may be associated with the objects themselves or with the lithography system. For example, the disturbance may result from a physical contact between one object and another object. When the type of lithography is contact lithography, a contact between contacting surfaces of the patterning tool and the substrate may induce a drift or a shift in a relative alignment therebetween, for example. In another example, the disturbance is due to a mechanical drift or slippage of a mechanism of the contact lithography system as the patterning tool is moved into contact with the substrate. As used herein, mechanical drift or slippage is defined as an unwanted or unintended motion of the lithography system.

FIG. 2 illustrates a flow chart of employing 200 feedback control according to an embodiment of the present invention. In some embodiments, employing 200 feedback control is equivalent to employing 120 nDSE-based feedback control mentioned above for the method 100 of maintaining an alignment. As illustrated in FIG. 2, employing 200 feedback control comprises acquiring 210 an image of the objects after a disturbance. In particular, the image is acquired 210 after a disturbance that degrades an alignment of the objects relative to the established 110 initial alignment. In some embodiments, acquiring 210 an image is performed after a disturbance is detected (e.g. using a vibration sensor). In other embodiments, the image is simply acquired 210 periodically during lithography. In some embodiments, acquiring 210 an image employs an optical sensor of the lithography system. In these embodiments, acquiring 210 an image comprises optically imaging and recording an image of the objects. For example, a microscope mounted camera may be employed to acquire 210 the image. The acquired 210 image is then stored in a memory. In other embodiments, acquiring 210 an image employs a non-optical imaging means to image the objects including, but not limited to, X-ray laminography.

Employing 200 feedback control further comprises estimating 220 a relative displacement of the objects using nDSE applied to the image. In particular, nDSE is applied to the acquired 210 image and a reference image. In some embodiments, the reference image represents the objects prior to the disturbance. Estimating 220 a relative displacement produces an estimate of the relative displacement by sensing a difference evident between the acquired 210 image and the reference image according to nDSE. The estimated 220 relative displacement represents a position error of the objects due to the disturbance.

In some embodiments, estimating 220 a relative displacement uses statistical image correlation-based nDSE. In other embodiments, phase delay detection-based (PDD-based) nDSE is used for estimating 220 a relative displacement. In yet other embodiments, estimating 220 a relative displacement uses both PDD-based nDSE and statistical image correlation-based nDSE. In still other embodiments, other nDSE methods such as feature extraction-based nDSE are used for estimating 220 a relative displacement instead of or in addition to one or both of statistical image correlation-based nDSE and PDD-based nDSE.

Employing 200 feedback control further comprises adjusting 230 relative positions of one or more of the objects to reduce the relative displacement. For example, a position of one of the objects may be adjusted 230 by instructing a positioning system of the lithography system to move the object relative to others of the objects in a manner that reduces the relative displacement. In terms of the position error, the position system moves the object by (−Δx, −Δy) when the position error is estimated by nDSE to be (Δx, Δy). After the object is moved, the position error is reduced and, in some embodiments, the position error is minimized. As such, the employed 200 feedback control applies negative feedback of the estimated relative displacement to reposition the objects after the displacement, in some embodiments. In some embodiments, acquiring 210 an image, estimating 220 a relative displacement, and adjusting 230 relative positions of one or more of the objects are repeated at a rate that exceeds a Nyquist frequency of the disturbance to facilitate real-time feedback control during lithography.

In some embodiments (not illustrated), the method 100 of maintaining an alignment further comprises acquiring a reference image of the objects. The reference image is acquired after the initial alignment is established 110. For example, the reference image may be acquired by the same optical sensor used in acquiring 210 an image described above. In some embodiments, the reference image is acquired before the disturbance degrades the alignment of the objects. In some embodiments, acquiring the reference image provides the reference image used in estimating 220 a relative displacement described above with respect to employing 200 feedback control. In some embodiments, the reference image is acquired after adjusting 230 relative positions of one or more of the objects. In particular, acquiring the reference image after adjusting 230 relative positions provides a new reference image to replace a previously acquired reference image, according to some embodiments.

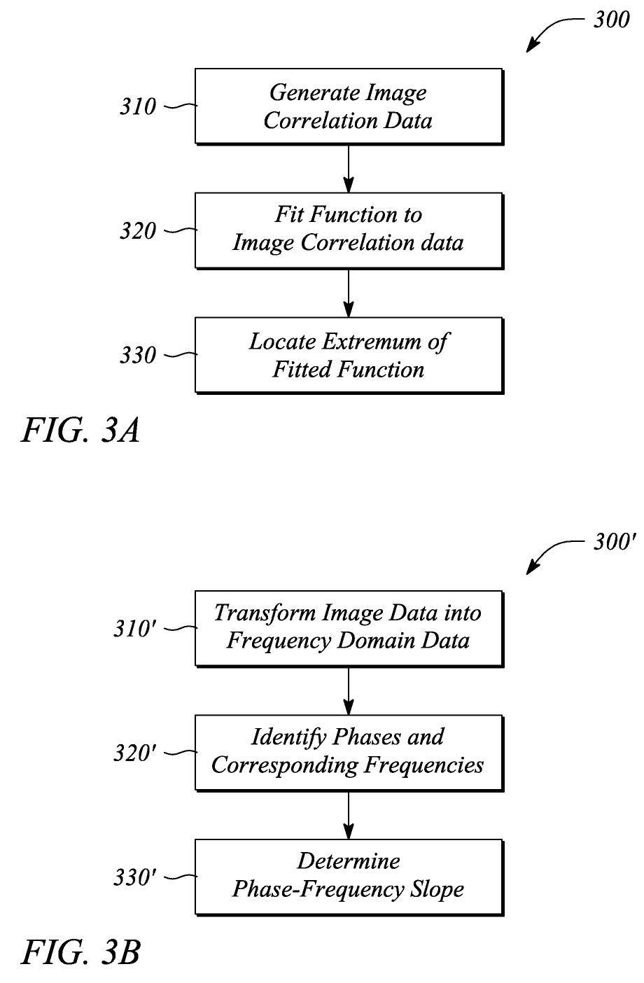

FIG. 3A illustrates an embodiment of using 300 nanoscale displacement sensing and estimation (nDSE) according to the present invention. In particular, FIG. 3A illustrates using 300 statistical image correlation-based nDSE to estimate a relative displacement after a disturbance of the objects, according to an embodiment. In some embodiments, the statistical image correlation-based nDSE is used 300 in conjunction with employing 120 nDSE-based feedback control described above with respect to method 100 of maintaining an alignment during lithography. Further, in some embodiments, estimating 220 a relative displacement described above with respect to employing 200 feedback control uses 300 statistical image correlation-based nDSE that is illustrated in FIG. 3A.

As illustrated in FIG. 3A, using 300 statistical image correlation-based nDSE comprises generating 310 image correlation data. Image correlation data comprises data representing a correlation of a reference image of the objects acquired before the disturbance and an image of the objects acquired after the disturbance. Using 300 statistical image correlation-based nDSE further comprises fitting 320 a function to the image correlation data. In some embodiments, the function is a continuous function of two variables. Using 300 statistical image correlation-based nDSE further comprises determining 330 a location of an extremum of the function after fitting 320. For example, the extremum may be a minimum of the function after fitting. The location of the extremum represents an estimate of a relative displacement of the objects due to the disturbance. The estimate of the relative displacement determined by using 300 may be the relative displacement estimate produced by estimating 200 a relative displacement, in some embodiments. Further details of statistical image correlation-based nDSE are described further in Gao et al., U.S. Patent Application Publication, US 2006-0045313 A1, referenced above.

FIG. 3B illustrates a flow chart of another embodiment using 300′ nanoscale displacement sensing and estimation (nDSE) according to the present invention. In particular, FIG. 3B illustrates using 300′ phase delay detection-based (PDD-based) nDSE to estimate a relative displacement after a disturbance of the objects, according to an embodiment. In some embodiments, the PDD-based nDSE is used 300′ in conjunction with employing 120 nDSE-based feedback control described above with respect to method 100 of maintaining an alignment. Further, in some embodiments, estimating 220 a relative displacement described above with respect to employing 200 feedback control uses 300′ PDD-based nDSE illustrated in FIG. 3B.

As illustrated in FIG. 3B, using 300′ PDD-based nDSE comprises transforming 310′ image data into frequency domain data. For example, a Fourier transform or a discrete Fourier transform may be applied to the image data to transform 310′ the image data. The image data represents a reference image of the objects acquired before the disturbance and an image of the objects acquired after the disturbance. Using 300′ PDD-based nDSE further comprises identifying 320′ phases and corresponding frequencies within the frequency domain data. Using 300′ PDD-based nDSE further comprises determining 330′ a phase-frequency slope from the identified 320′ phases and corresponding frequencies. The phase-frequency slope represents an estimate of a relative displacement. The phase-frequency slope is a slope of a plane through the frequency domain data. For example, the plane may be fitted to at least two essentially noise-free, undistorted identified 320′ phases within the frequency domain data. Ideally, the plane passes through an origin of the frequency domain providing a third point that defines the plane. The estimate of the relative displacement determined by using 300′ PDD-based nDSE may be the relative displacement estimate produced by estimating 220 a relative displacement, in some embodiments.

In some embodiments, determining 330′ a phase-frequency slope comprises identifying at least one frequency of the identified 320′ phases and corresponding frequencies, the at least one frequency having a known property. In these embodiments, determining 330′ a phase-frequency slope further comprises assigning weights to the identified 320′ phases, the weights being dependent on the at least one frequency of the identified 320′ phases. For example, the known property and the at least one frequency associated therewith may be frequencies that are expected to be noisy based on known characteristics of the lithography system. In some embodiments, a zero weight is assigned. The assigned weights are used in determining 330′ a phase-frequency slope, in some of these embodiments. Further details of PDD-based nDSE are described further in Gao et al., in U.S. Patent Application Publication, US 2006-0045314 A1, referenced above.

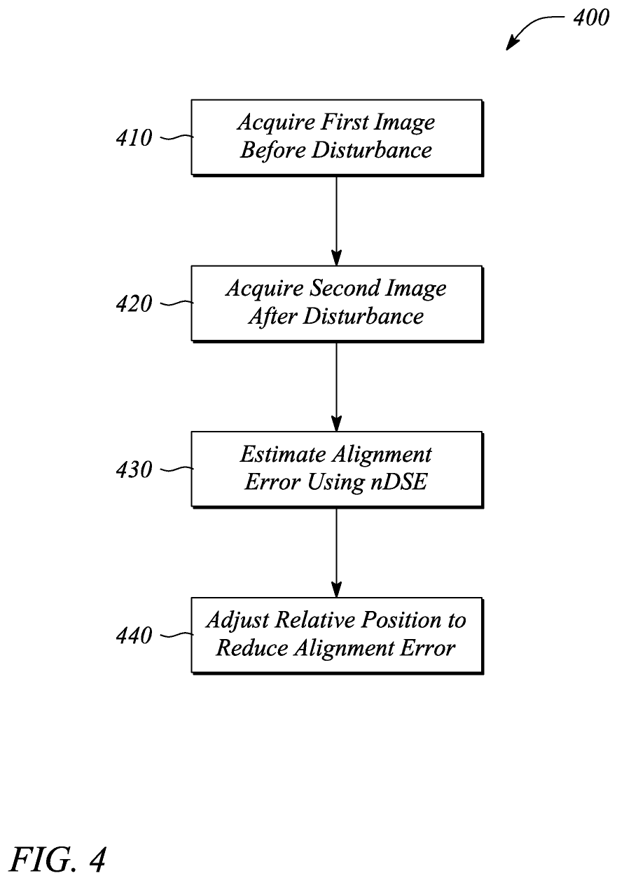

FIG. 4 illustrates a flow chart of a method 400 of disturbance compensation during contact lithography according to an embodiment of the present invention. A disturbance that is compensated by the method 400 may be any of the disturbances discussed above as well as any combination thereof. In some embodiments, the method 400 of disturbance compensation maintains an alignment during contact lithography.

As illustrated in FIG. 4, the method 400 of disturbance compensation comprises acquiring 410 a first image of a patterning tool and a substrate being patterned by the contact lithography. In some embodiments, the patterning tool and the substrate are imaged simultaneously. For example, a simultaneous image may be obtained by imaging the substrate through a partially transparent patterning tool. The first image is acquired 410 after an alignment is established between the patterning tool and the substrate. In some embodiments, the established alignment is an initial alignment that is established at a beginning of contact lithography. In some embodiments, the first image is a reference image.

The method 400 of disturbance compensation further comprises acquiring 420 a second image of the patterning tool and the substrate after a disturbance to the alignment that degrades the alignment. In particular, the second image is acquired 420 either after a disturbance is detected or after a disturbance is suspected. For example, the second image may be acquired 420 when a sensor detects a disturbance. Alternatively, the second image is acquired 420 periodically during contact lithography expecting or assuming that a disturbance has happened.

The method 400 of disturbance compensation further comprises estimating 430 an alignment error induced by the disturbance. In particular, estimating 430 an alignment error is performed using nDSE applied to the first image and the second image. In various embodiments, using nDSE may comprise using one or more of PDD-based nDSE, statistical image correlation-based nDSE, and feature extraction-based nDSE. For example, using nDSE applied to the images may comprise using 300, 300′ nDSE described above with respect to FIGS. 3A and 3B, respectively.

The method 400 of disturbance compensation further comprises adjusting 440 a relative position of the patterning tool and the substrate to reduce the alignment error. In particular, the estimated 430 alignment error is provided to a positioning system of the contact lithography system. The positioning system moves one or both of the patterning tool and the substrate in a manner responsive to the provide alignment error. The movement reduces the alignment error. In some embodiments, acquiring 420 a second image, estimating 430 an alignment error, and adjusting 440 a relative position are repeated to further reduce and in some embodiments, are repeated to minimize the alignment error. In some embodiments, acquiring 420 a second image, estimating 430 an alignment error, and adjusting 440 a relative position are repeated at a rate that is equal to or greater than a Nyquist frequency of the disturbance to facilitate real-time disturbance compensation during contact lithography.

In some embodiments, one or both of the method 100 of maintaining an alignment and the method 400 of disturbance compensation are employed in a contact lithography alignment system. For example, the method 100 of maintaining may be implemented as instructions of a computer program stored in a memory of the contact lithography alignment system. A processor of the contact lithography system may execute the instructions to apply the method 100 to maintain an alignment. Similarly, the method 400 of disturbance compensation may be implemented as instructions of a computer program stored in a memory of the alignment system, and executed by the processor, such that the method 400 may be applied to the contact lithography alignment system to provide disturbance compensation.

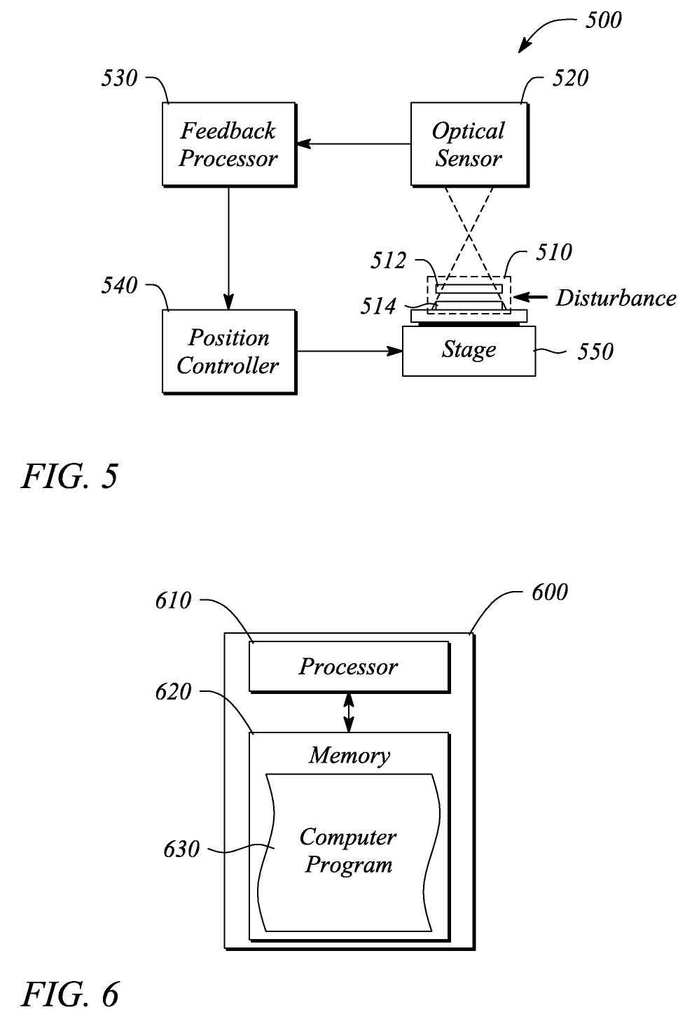

FIG. 5 illustrates a block diagram of a contact lithography alignment system 500 according to an embodiment of the present invention. The contact lithography alignment system 500 uses images of one or more objects 510 and nDSE to determine and reduce a disturbance-induced relative displacement of the objects 510. In particular, the contact lithography alignment system 500 one or both of maintains an alignment and provides disturbance compensation of the alignment of the objects.

As illustrated in FIG. 5, the contact lithography alignment system 500 comprises an optical sensor 520. The optical sensor 520 produces an image of the objects 510 being aligned. For example, the objects 510 being aligned may be a combination of a patterning tool 512 and a substrate 514 being patterned using contact lithography. The optical sensor 520 may be a monochrome digital camera such as a Pulnix TM-1400CL having a 1.4M pixel CCD that provides 8-bit pixel values, a pixel size of 4.65 microns in the image plane, and a maximum frame rate of 30 Hz, for example. The optical sensor 520 produces the image after a disturbance of the objects 510. The disturbance to the objects 510 is illustrated by an arrow labeled Disturbance in FIG. 5. In some embodiments, the optical sensor 520 further produces a reference image of the objects 510 before the disturbance.

The contact lithography alignment system 500 further comprises a feedback processor 530 providing nDSE. The feedback processor 530 receives the image or data representing the image from the optical sensor 520. The feedback processor 530 determines an alignment error from the image using nDSE. The provided nDSE comprises one or more of statistical image correlation-based nDSE, PDD-based nDSE, and feature extraction-based nDSE, in various embodiments. The feedback processor 530 produces an output representing the determined alignment error, in some embodiments. The alignment error represents a positional deviation from an initial alignment of the objects 510.

The contact lithography alignment system 500 further comprises a position controller 540. The alignment error from the feedback processor 530 is communicated to the position controller 540. The position controller 540 receives the determined alignment error (e.g., feedback processor output signal) and controls positioning of the objects 510. In particular, the position controller 540 adjusts relative positions of the objects 510 to reduce the alignment error.

In some embodiments, the position controller 540 provides an input to a stage 550 upon which is mounted one or more of the objects 510 (e.g., a substrate). The stage 550 enables controlled movement of the stage-mounted objects 510. The provided input from the position controller 540 instructs the stage 550 to move the objects 510. In some embodiments, the stage 550 is a precision stage 550. For example, the precision stage 550 may be an N-point XY200Z20A-A nano-positioning stage manufactured by nPoint Incorporated, Madison, Wis. In an example, only the substrate 514 may be mounted to the precision stage 550 and the patterning tool 512 is fixed. In this example, a position of the substrate 514 is adjusted relative to a patterning tool 512 position. In another example, the patterning tool 512 is moved (e.g., by another stage or similar positioning system, not illustrated) instead of or in addition to the stage-mounted substrate 514 to reduce the alignment error.

In some embodiments, the reduced alignment error compensates for a disturbance of the objects 510 during contact lithography. In some embodiments, the initial alignment of the objects 510 establishes a desired relative position of the objects 510. For example, the desired relative position may represent an alignment of a pattern on the patterning tool 512 with a receiving surface of the substrate 514. In some embodiments, the reference image is produced following the initial alignment and prior to the disturbance.

FIG. 6 illustrates a block diagram of a feedback processor 600 providing nanoscale displacement sensing and estimation (nDSE) according to an embodiment of the present invention. In particular, the provided nDSE may comprise one or more of statistical image correlation-based nDSE, PDD-based nDSE, and feature extraction-based nDSE. In some embodiments, the feedback processor 600 is employed as the feedback processor 530 of the contact lithography alignment system 500. In some embodiments, the feedback processor 600 essentially implements one or both of the method 100 of maintaining an alignment and the method 400 of disturbance compensation described above.

As illustrated in FIG. 6, the feedback processor 600 comprises a processor 610, memory 620 and a computer program 630. The computer program 600 is stored in the memory 620 and executed by the processor 610. The computer program 630 comprises instructions that, when executed by the processor 610, implement estimating a relative displacement using the nDSE applied to an image and a reference image of one or more objects. The estimated relative displacement represents an alignment error. For example, the objects may be the objects 510. In some embodiments, the instructions of the computer program 630 further implement acquiring an image and a reference image from an optical sensor. For example, the optical sensor may be the optical sensor 520.

In some embodiments, the instructions of the computer program 630 further implement statistical image correlation-based nDSE comprising fitting a function to correlation data for the image and the reference image and identifying an extremum of the function after fitting. The extremum, a minimum or a maximum of the function, provides the estimate. In some embodiments, the instructions of the computer program 630 further implement phase delay detection-based (PDD-based) nDSE comprising performing a frequency transform of image data representing the image and the reference image to produce frequency domain data. The instruction further implement finding a slope associated with a phase of the frequency domain data. The slope provides the estimate of the relative displacement. In some embodiments, the instructions implement feature extraction-based nDSE comprising identifying, locating and comparing corresponding image features and patterns in the image and reference image. The comparison determines the estimate of relative displacement.

Thus, there have been described embodiments of a contact lithography alignment system and methods that employ nDSE to one or both of maintain an alignment and provide disturbance compensation during lithography. It should be understood that the above-described embodiments are merely illustrative of some of the many specific embodiments that represent the principles of the present invention. Clearly, numerous other arrangements can be devised without departing from the scope of the present invention as defined by the following claims.

What is claimed is:

1. A method of maintaining an alignment during lithography comprising:
establishing an initial alignment of one or more objects; and
employing feedback control of relative positions of one or more of the objects to maintain the alignment during lithography, wherein the feedback control comprises using nanoscale displacement sensing and estimation (nDSE).

2. The method of maintaining an alignment of claim 1, wherein employing feedback control comprises:
acquiring an image of the objects after a disturbance, the disturbance degrading the alignment;
estimating an relative displacement using the nDSE applied to the image and to a reference image of the objects; and
adjusting relative positions of one or more of the objects to reduce the relative displacement.

3. The method of maintaining an alignment of claim 1, further comprising acquiring a reference image of the objects after the initial alignment is established and before a disturbance.

4. The method of maintaining an alignment of claim 1, wherein the lithography is contact lithography, the objects comprising a patterning tool and a substrate being patterned, and wherein the objects experience a disturbance, the disturbance resulting from a contact between a contacting surface of the patterning tool and a contacting surface of the substrate.

5. The method of maintaining an alignment of claim 1, wherein the objects experience a disturbance, the disturbance resulting from one or more of a vibration, a temperature difference, and a mechanical slippage.

6. The method of maintaining an alignment of claim 1, wherein using nDSE comprises:
generating image correlation data, the image correlation data representing a correlation of a reference image of the objects acquired before a disturbance of the objects and an image of the objects acquired after the disturbance;
fitting a function to the image correlation data; and
determining a location of an extremum of the function after the function is fitted, the location representing an estimate of a relative displacement, the relative displacement being a result of the disturbance.

7. The method of maintaining an alignment of claim 1, wherein using nDSE comprises:
transforming image data into frequency domain data, the image data representing a reference image of the objects acquired before a disturbance of the objects and an image of the objects acquired after the disturbance;
identifying phases and corresponding frequencies within the frequency domain data;
determining a phase-frequency slope from the phases and corresponding frequencies, the phase-frequency slope representing an estimate of a relative displacement, the relative displacement being a result of the disturbance.

8. The method of maintaining an alignment of claim 1 used in a contact lithography system, the method being implemented as instructions of a computer program executed by the contact lithography system during contact lithography to maintain the alignment.

9. A method of disturbance compensation during contact lithography, the method comprising:
acquiring a first image of a patterning tool and a substrate being patterned by the contact lithography, the first image being acquired after establishing an alignment between the patterning tool and the substrate;
acquiring a second image of the patterning tool and the substrate after a disturbance of the alignment, the disturbance degrading the alignment;
estimating an alignment error induced by the disturbance using nanoscale displacement sensing and estimation (nDSE) applied to the first image and the second image; and
adjusting a relative position of the patterning tool and the substrate to reduce the alignment error.

10. The method of disturbance compensation of claim 9, wherein estimating an alignment error using nDSE comprises employing one or both of statistical image correlation-based nDSE and phase delay detection-based (PDD-based) nDSE, and wherein the disturbance is one or more of induced by a contact between the patterning tool and the substrate, associated with differential vibration of the patterning tool and the substrate, produced by a temperature differential between the patterning tool and the substrate, and a result of mechanical slippage of a system performing the contact lithography.

11. The method of disturbance compensation of claim 9, wherein acquiring a second image, estimating an alignment error and adjusting a relative position are repeated at a rate that exceeds a Nyquist frequency of the disturbance to facilitate real-time disturbance compensation during contact lithography.

12. A contact lithography alignment system comprising:
an optical sensor that produces an image of one or more objects being aligned;
a feedback processor providing nanoscale displacement sensing and estimation (nDSE), the feedback processor receiving the image from the optical sensor and determining an alignment error from the image using the nDSE, the alignment error being relative to an initial alignment of the objects; and
a position controller that adjusts relative positions of one or more of the objects to reduce the alignment error determined by the feedback processor.

13. The contact lithography alignment system of claim 12, wherein the reduced alignment error compensates for a disturbance of the objects during contact lithography.

14. The contact lithography alignment system of claim 12, wherein the objects comprise a patterning tool and a substrate being patterned, the initial alignment establishing a relative positioning of the patterning tool and the substrate, the position controller adjusting the relative positioning to reduce the alignment error.

15. The contact lithography alignment system of claim 12, wherein the optical sensor further produces a reference image of the objects following the initial alignment of the objects and prior to a disturbance of the objects.

16. The contact lithography alignment system of claim 12, wherein the nDSE comprises one or both of statistical image correlation-based nDSE and phase delay detection-based (PDD-based) nDSE using the image and a reference image of the objects.

17. The contact lithography alignment system of claim 12, wherein the feedback processor comprises:
a processor;
a memory; and
a computer program stored in the memory and executed by the processor, the computer program comprising instruction that, when executed by the processor, implement estimating an relative displacement using the nDSE applied to the image and a reference image of the objects, the relative displacement representing the alignment error of the objects.

18. The contact lithography alignment system of claim 17, wherein the instructions further implement acquiring the image and the reference image from the optical sensor.

19. The contact lithography alignment system of claim 17, wherein the instructions further implement statistical image correlation-based nDSE comprising fitting a function to correlation data for the image and the reference image and locating an extremum of the function after fitting, the extremum providing an estimate the relative displacement.

20. The contact lithography alignment system of claim 17, wherein the instructions further implement phase delay detection-based (PDD-based) nDSE comprising performing a frequency transform of image data representing the image and the reference image to produce frequency domain data and determining a phase-frequency slope associated with phases in the frequency domain data, the phase-frequency slope providing an estimate of the relative displacement.
